(19) United States
(12) Patent Application Publication
(10) Pub. No.: US 2007/0145433 A1
(43) Pub. Date: Jun. 28, 2007

(54) SEMICONDUCTOR DEVICE

(76) Inventor: Jae-Hwan Shim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/614,658

(22) Filed: Dec. 21, 2006

(30) Foreign Application Priority Data
Dec. 28, 2005 (KR) 10-2005-0131505

(51) Int. Cl. H01L 29/76

(52) U.S. Cl. 257/288

(57) ABSTRACT

Embodiments relate to a semiconductor device and a method for manufacturing the same. According to embodiments, a semiconductor device may include an active area defined on a semiconductor substrate by a first isolation layer and a second isolation layer, a diode in the active area placed at one side of the first isolation layer, a transfer gate formed at one side of the diode, and an electrode on the diode and the transfer gate.

The present application claims priority under 35 U.S.C. 119 and 35 U.S.C. 365 to Korean Patent Application No. 10-2005-0131505 (filed on Dec. 28, 2005), which is hereby incorporated by reference in its entirety.

### BACKGROUND

As semiconductor devices have become more highly integrated, size of components and regions, including a transistor area, may be reduced. As a result, a gate length, an interval between gates, and an interval between interconnections may also be reduced. Thus, ensuring gap filling characteristics may be an important issue when forming an interlayer dielectric layer, which may be an insulator between the above-mentioned conductive lines.

A boron-phosphorous-silicon glass (BPSG) layer may be used as an interlayer dielectric layer. However, because of various problems that maybe caused by a high temperature process, an oxide layer formed by a high-density plasma chemical vapor deposition (HDP-CVD) process may be used as the interlayer dielectric layer.

Referring to FIG. 1, a related art semiconductor device may include gate insulating layer 120, gate 130, and spacer 140 on semiconductor substrate 100. Semiconductor substrate 100 may include an active area that may be defined by isolation layer 110. In addition, source area 151 and drain area 152 may be formed in substrate 100. Accordingly, plasma may be easily concentrated onto edges of a channel area in the lower part of gate 130 and onto edges of isolation layer 110, when performing a plasma process such as the HDP-CVD process.

If the plasma is concentrated as described above, however, a plasma charging P may occur at the concentrated part after the plasma process has been performed. This may cause problems such as a junction leakage current.

### SUMMARY

Embodiments relate to a semiconductor device and a method for manufacturing the same.

Embodiments relate to a semiconductor device and a method for manufacturing the same, that may be capable of preventing a plasma charging caused by a plasma process.

In embodiments, a semiconductor device may include an active area defined on a semiconductor substrate by a first isolation layer and a second isolation layer, a diode in the active area placed at one side of the first isolation layer, a transfer gate formed at one side of the diode, and an electrode on the diode and the transfer gate.

In embodiments, a method for manufacturing a semiconductor device may include defining an active area on a semiconductor substrate by a first isolation layer and a second isolation layer, forming a diode in the active area placed at one side of the first isolation layer, forming a transfer gate at one side of the diode, and forming an electrode on the diode and the transfer gate.

### BRIEF DESCRIPTION OF THE DRAWINGS

FIG. 1 is an example sectional diagram illustrating a related art semiconductor device;

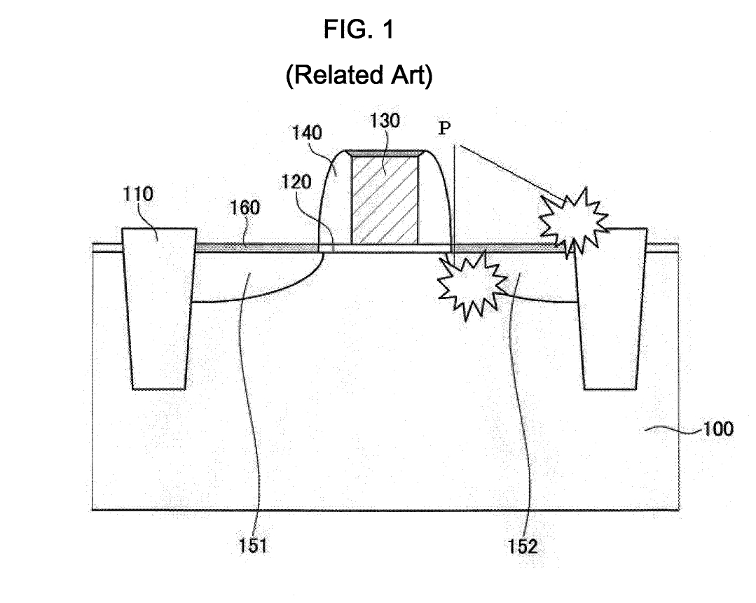

FIG. 2 is an example sectional diagram illustrating a semiconductor device according to embodiments; and

FIG. 3 is an example diagram illustrating a semiconductor device according to embodiments.

### DETAILED DESCRIPTION

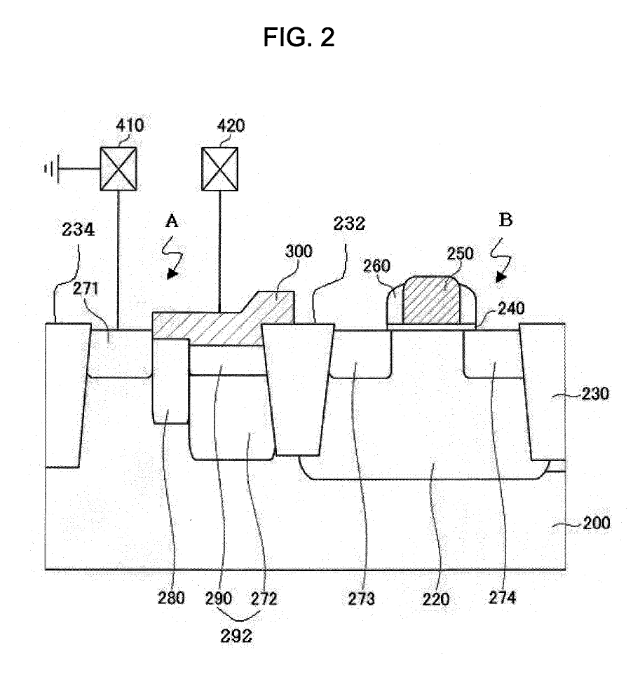

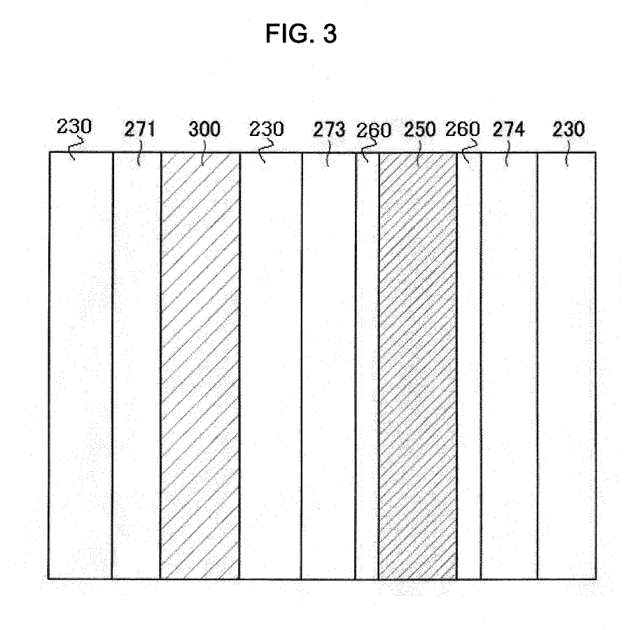

Referring to FIGS. 2 and 3, first active area A may be defined on semiconductor substrate 200 by first isolation layer 232 and second isolation layer 234. In addition, second active area B may be defined on semiconductor substrate 200 by first isolation layer 232 and third isolation layer 230.

Pwell 220, N⁺ source area 273, and N⁺ drain area 274 may be formed in second active area B of semiconductor substrate 200. Gate insulating layer 240, gate 250, and spacer 260 may be formed on an upper part of the resultant structure.

A high-density N⁺ impurity area 272 maybe formed in first active area A of the semiconductor substrate 200, and may be adjacent to a lower part of the first isolation layer 232. PN junction diode 292, which may include high-density P⁺ impurity area 290, may be formed on the upper part of high-density N⁺ impurity area 272.

In addition, high-density N+junction area 271 may be formed adjacent to second isolation layer 234, and may be spaced apart from diode 292.

In addition, transfer gate 280 may be formed between diode 292 and high-density N⁺ junction area 271. Electrode 300 may be formed on diode 292, transfer gate 280, and first isolation layer 232.

Transfer gate 280 may be formed into a high-density P⁺ area through an ion implantation. According to embodiments, transfer gate 280 may be formed into the high-density P⁺ area through implanting boron ions.

In embodiments, electrode 300 may include a poly-silicon layer and may be connected to supply voltage 420 through an interconnection process. High-density N⁺ junction area 271 may be connected to ground terminal 410.

According to embodiments, when performing a plasma process, for example, when performing an HDP-CVD process to form an interlayer dielectric layer, the plasma may be concentrated onto edges of a channel area in the lower part of gate 250 or onto edges of isolation layers 230, 232 and 234. This may cause a plasma charging to be incurred thereon. According to embodiments, the plasma may discharge from the device to an exterior through a structure formed on first active area A.

Hence, according to embodiments, if the plasma is charged onto the edges of a channel area in the lower part of gate 250 in the second active area B or onto edges of the isolation layers 230, 232 and 234, the plasmamaybe confined in N⁺ impurity area 272 of PN junction diode 292 by the supply voltage applied through electrode 300. Accordingly, such plasma may be moved to high-density N⁺ junction area 271 through transfer gate 280, and may be discharged through ground terminal 410.

Thus, a semiconductor device according to embodiments may prevent a junction leakage current of the device, because the plasma charging may not occur even if a plasma process is performed.

In addition, a semiconductor device according to embodiments may not require an additional electrostatic discharge (ESD) protect structure, because a structure formed in the first active area may serve as the ESD protect structure after forming a chip.

A semiconductor device according to embodiments may prevent a discharge and a junction leakage current by restricting the plasma charging that may be caused after the plasma process, thereby improving the product yield and the reliability of the device.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a semiconductor substrate having an active area defined by a first isolation layer and a second isolation layer;
a diode in the active area configured to be proximally located to the first isolation layer;
a transfer gate formed at one side of the diode; and
an electrode over the diode and the transfer gate.

2. The device of claim 1, further comprising a junction area between the transfer gate and the second isolation layer.

3. The device of claim 2, wherein the diode comprises a PN junction diode, and is configured to be interposed between the transfer gate and the first isolation layer.

4. The device of claim 3, wherein the diode comprises:
a high-density N type doping area; and
a high-density P type doping area over the high-density N type doping area.

5. The device of claim 4, wherein the diode is adjacent to the first isolation layer.

6. The device of claim 4, wherein the electrode is configured to be electrically connected to a supply voltage, and the junction area is configured to be grounded.

7. The device of claim 6, wherein the junction area is adjacent to the second isolation layer.

8. The device of claim 7, wherein the junction area comprises a high-density N⁺ area.

9. The device of claim 7, wherein the electrode comprises a poly-silicon layer.

10. The device of claim 9, wherein the electrode is configured to be in electrically connected with on the diode, the transfer gate, and the first isolation layer.

11. A method comprising:
defining an active area on a semiconductor substrate by a first isolation layer and a second isolation layer;
forming a diode in the active area proximally located to the first isolation layer;
forming a transfer gate at one side of the diode; and
forming an electrode over the diode and the transfer gate.

12. The method of claim 11, further comprising forming a junction area between the transfer gate and the second isolation layer.

13. The method of claim 12, wherein the diode comprises a PN junction diode.

14. The method of claim 13, wherein forming the diode comprises:
forming a high-density N type doping area at a lower part of the diode; and
forming a high-density P type doping area over the high-density N type doping area.

15. The method of claim 14, wherein the diode is adjacent to the first isolation layer.

16. The method of claim 14, wherein the electrode is configured to make electrical contact with a supply voltage, and the junction area is configured to make contact with ground.

17. The method of claim 14, wherein the junction area is adjacent to the second isolation layer and comprises a high-density N⁺ area.

18. The method of claim 17, wherein the electrode comprises a poly-silicon layer, the electrode is formed on the diode, the transfer gate, and the first isolation layer, and the electrode is configured to be electrically connected to the diode, the transfer gate, and the first isolation layer.

19. The method of claim 17, wherein the junction area is configured to receive an accumulated plasma charge within the active area or an adjacent active area from the transfer gate and discharge the accumulated plasma charge to ground.

20. The method of claim 11, wherein the diode comprises a PN junction diode.
